(19) United States
(12) Patent Application Publication
(10) Pub. No.: US 2021/0267055 A1
(43) Pub. Date: Aug. 26, 2021

(54) CIRCUIT BOARD AND MOTOR

(71) Applicant: NIDEC SERVO CORPORATION, Kiryu-shi (JP)

(72) Inventors: Tomoaki USHIKI, Kiryu-shi (JP); Harumasa MASUDA, Kiryu-shi (JP)

(21) Appl. No.: 17/179,463

(22) Filed: Feb. 19, 2021

(30) Foreign Application Priority Data
Feb. 20, 2020 (JP) 2020-027063

(51) Int. Cl. H05K 1/11; H02K 11/33; H05K 1/18; H05K 1/09

(52) U.S. Cl. CPC H05K 1/111; H02K 11/33; H05K 2201/1009; H05K 1/09; H05K 1/181

(57) ABSTRACT

A circuit board includes a board, a land on the board, and an electronic component soldered to the land, the electronic component including a surface with a back surface electrode portion, the surface opposing the board, the land including an electrode land portion and a protruding land portion, the back surface electrode portion opposing the electrode land portion in a state in which the electronic component and the board are soldered, and the protruding land portion and the electrode land portion being integrated.

### CROSS REFERENCE TO RELATED APPLICATION

The present invention claims priority under 35 U.S.C. § 119 to Japanese Patent Application No. 2020-027063 filed on Feb. 20, 2020, the entire contents of which are hereby incorporated herein by reference.

### 1. FIELD OF THE INVENTION

The present invention relates to a circuit board and a motor.

### 2. BACKGROUND

Various drive controls for rotating a motor at a desired speed conventionally have been implemented. Electronic components constituting a motor drive circuit that controls drive of the motor are mounted on a board. In recent years, as circuits used for motors and the like are reduced in size, the number of electronic components of a type that are surface-mounted on a board increases.

Some electronic components of a surface-mounted type are each provided on its surface with an electrode portion to be soldered to a board, the surface facing the circuit board, and a soldered state thereof cannot be checked after mounting. However, equipment requiring high reliability needs to be checked whether electronic components are reliably soldered. To check whether the electronic components are surely soldered, checking with an X-ray or an in-circuit tester (ICT) is conceivable.

Unfortunately, the checking with an X-ray has problems such as capital investment being required, high cost, and long inspection time. Then, the checking with an ICT has a problem in that while an energized state at the time of inspection can be checked, an imperfect solder joint cannot be checked.

### SUMMARY

According to an example embodiment of the present disclosure, a circuit board includes a board, a land on the board, and an electronic component soldered to the land. The electronic component includes a surface with a back surface electrode portion, the surface opposing the board, the land including an electrode land portion and a protruding land portion, the back surface electrode portion opposing the electrode land portion in a state in which the electronic component and the board are soldered, and the protruding land portion and the electrode land portion being integrated.

According to another example embodiment of the present disclosure, a circuit board includes a board, a first land on the board, and an electronic component soldered to the first land. The electronic component includes a surface with a first back surface electrode portion, the surface opposing the circuit board, the first back surface electrode portion opposing a first electrode land portion provided on the first land, the first back surface electrode portion extending to an end portion of the electronic component in a direction parallel to a mounting surface of the board and extending to a side surface of the electronic component, the side surface being orthogonal to the mounting surface of the board, the first land including a protruding land portion connected to the first electrode land portion at a position that does not oppose the electronic component, and the first land provided with the protruding land portion being integrated with the first land provided with the first electrode land portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a sectional view illustrating a motor according to a/first example embodiment of the present disclosure taken along a plane orthogonal to Y-axis and passing through a center axis J.

FIG. 2 is a perspective view of a motor 10 of FIG. 1.

FIG. 3 is a plan view of the motor 10 of FIG. 2 with a motor housing 23 removed as viewed from above.

FIG. 4 is a plan view illustrating a board defining a circuit board according to the first example embodiment of the present disclosure.

FIG. 5 is a plan view illustrating a configuration of the circuit board according to the first example embodiment of the present disclosure.

FIG. 6 is a bottom view of an electronic component illustrated in FIG. 5 as viewed from its surface facing a board.

FIG. 7 is a plan view illustrating the vicinity of a protruding land portion 95a in an enlarged manner, in which an electronic component 92 is properly soldered to a board 84.

FIG. 8 is a plan view illustrating the vicinity of the protruding land portion 95a in an enlarged manner, in which the electronic component 92 is poorly soldered to the board 84.

FIG. 9 is a plan view illustrating a board of a circuit board according to a second example embodiment of the present disclosure.

FIG. 10 is a plan view illustrating a configuration of the circuit board according to the second example embodiment of the present disclosure.

FIG. 11 is a bottom view of an electronic component illustrated in FIG. 10 as viewed from a surface opposed to a board.

FIG. 12 is a side view of the electronic component illustrated in FIG. 10 as viewed from a plane orthogonal to the board.

FIG. 13 is a plan view illustrating a board defining a circuit board according to a third example embodiment of the present disclosure.

FIG. 14 is a plan view illustrating a configuration of the circuit board according to the third example embodiment of the present disclosure.

FIG. 15 is a bottom view of an electronic component illustrated in FIG. 14 as viewed from its surface opposing a board.

### DETAILED DESCRIPTION

Hereinafter, motors according to example embodiments of the present disclosure will be described with reference to the accompanying drawings. In the following drawings, each structure may be different in contraction scale, number, or the like from an actual structure for easy understanding.

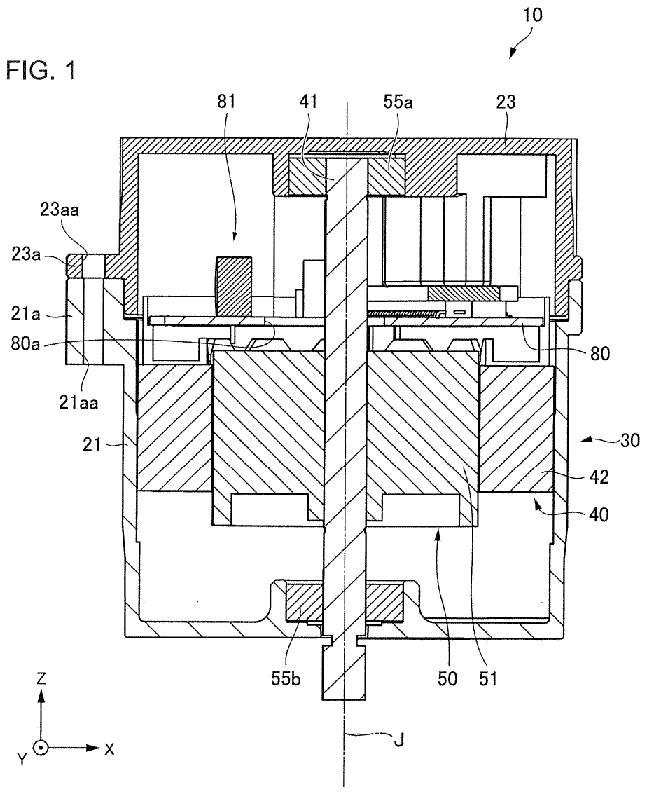

In the accompanying drawings, an XYZ coordinate system is shown appropriately as a three-dimensional orthogonal coordinate system. In the XYZ coordinate system, a Z-axis direction is assumed to be a direction parallel to an axial direction of a center axis J illustrated in FIG. 1. An X-axis direction is a radial direction with respect to the center axis J, as illustrated in FIG. 1. A Y-axis direction is a direction orthogonal to both the X-axis direction and the Z-axis direction. In any of the X-axis direction, the Y-axis direction, and the Z-axis direction, an arrow in each drawing indicates a positive side and a side opposite to the positive side is a negative side.

In the following description, a positive side of the Z-axis direction (+Z side) is called a “front side” or “one side”, and a negative side of the Z-axis direction (−Z side) is called a “rear side” or “the other side”. The rear side (the other side) and the front side (one side) are names used only for description and do not limit an actual positional relationship and direction. Unless otherwise particularly stated, a direction parallel to the center axis J (Z-axis direction) is simply called an “axial direction”, a radial direction about the center axis J is simply called a “radial direction”, and a circumferential direction around the center axis J, i.e., a direction around the center axis J is simply called a “circumferential direction”. A side toward the central axis J in the radial direction is called “radially inside”, and a side away from the center axis J is called “radially outside”.

Herein, the description, “extending in the axial direction”, refers to not only a case of strictly extending in the axial direction (Z-axis direction), but also a case of extending in a direction at an angle of less than 45° from the axial direction. Additionally, herein, the description, “extending in the radial direction”, refers to not only a case of strictly extending in the radial direction, i.e., in a direction perpendicular to the axial direction (Z-axis direction), but also a case of extending in a direction at an angle of less than 45° from the radial direction. The term, “parallel”, includes not only a case of being strictly parallel but also a case of inclination at an angle of less than 45°.

FIG. 1 is a sectional view illustrating a motor driven by a motor driving device according to a first example embodiment of the present disclosure taken along a plane orthogonal to Y-axis and passing through a center axis J.

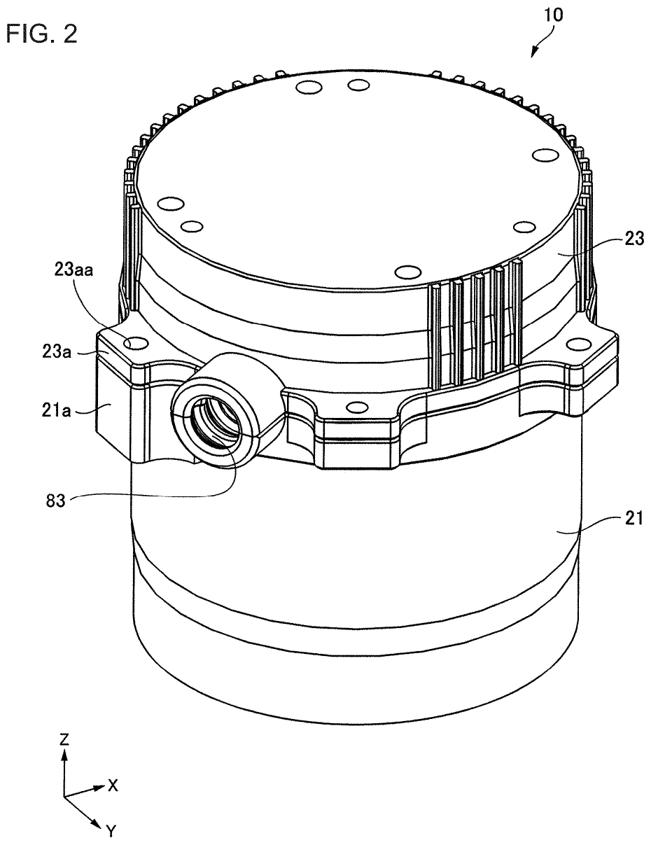

FIG. 2 is a perspective view of a motor 10 of FIG. 1.

In the present example embodiment, the motor 10 is a brushless DC motor. The motor 10 is provided with a motor assembly 30 including a rotor 50 and a stator 40, and motor housings 21 and 23 housing a circuit board 80 equipped with a drive circuit 81 and the like for driving the motor assembly 30. The rotor 50 includes a motor shaft 41 disposed along a central axis J extending in the axial direction. The stator 40 radially faces the rotor 50 with a gap therebetween. The motor housings 21 and 23 houses the circuit board 80 and the rotor 50 that are disposed from one side in the axial direction to the other side in the axial direction in the order listed above.

The stator 40 includes a stator yoke 42. The motor 10 includes the circuit board 80 on one side of the stator yoke 42 in the axial direction. The circuit board 80 includes a through-hole 80a passing through in the axial direction. The motor shaft 41 passes through the through-hole 80a. The motor 10 includes bearings 55a and 55b. The bearing 55a is disposed on the other side of the motor housing 23 in the axial direction. The bearing 55b is disposed on one side of the motor housing 21 in the axial direction. The bearing 55a is disposed in an end portion of the motor shaft 41 on one side in the axial direction. The bearing 55b is disposed in an end portion of the motor shaft 41 on the other side in the axial direction. The bearings 55a and 55b rotatably support the motor shaft 41. The bearings 55a and 55b are not particularly limited in shape, structure, and the like, and any publicly known bearing can be used.

The rotor 50 includes a rotor magnet 51. The rotor magnet 51 surrounds the motor shaft 41 around its axis and is fixed to the motor shaft 41.

The motor housing 21 has a bottomed tubular shape. The motor assembly 30 is housed radially inside the motor housing 21. The motor housing 21 may have a cylindrical shape or a square tubular shape. The motor housing 21 is formed by aluminum die-casting, for example. The motor 10 includes the motor housing 23 in a bottomed tubular shape on one side of the circuit board 80 in the axial direction. The motor housing 23 may have a cylindrical shape or a square tubular shape. The motor housing 23 is formed by aluminum die-casting, for example. The motor housing 21 opens on one side in the axial direction, and the motor housing 23 opens on the other side in the axial direction. The opening on one side of the motor housing 21 in the axial direction is closed by the motor housing 23, and the opening on the other side of the motor housing 23 in the axial direction is closed by the motor housing 21.

The motor housing 21 is provided in its end portion on one side in the axial direction with a flange portion 21a extending radially outward. The flange portion 21a includes a through-hole 21aa passing through in the axial direction. The motor housing 23 is provided in its end portion on the other side in the axial direction with a flange portion 23a extending radially outward. The flange portion 23a includes a through-hole 23aa passing through in the axial direction. The through-hole 21aa and the through-hole 23aa align at an axial position and a circumferential position, and thus the through-hole 21aa and the through-hole 23aa form a continuous through-hole. The motor housing 21 and the motor housing 23 can be fixed with a screw passing through the through-hole 21aa and the through-hole 23aa.

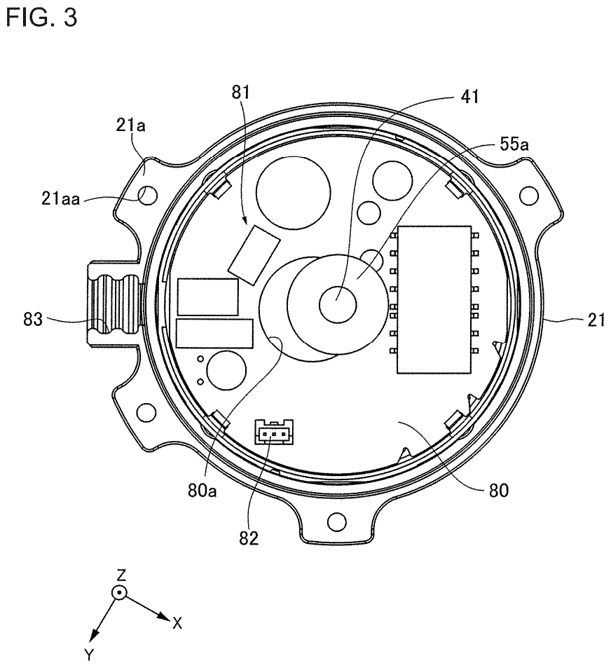

FIG. 3 is a perspective view illustrating the motor 10 of FIG. 2 with the motor housing 23 removed.

The circuit board 80 has a shape corresponding to a shape of a tubular hole of the motor housing 21. In the present example embodiment, the circuit board 80 is circular. The drive circuit 81 is composed of a plurality of electronic components. The drive circuit 81 includes at least one of an IGBT, a bridge diode, a MOSFET, an IPM, and a DC/DC converter, for example. The IGBT is an abbreviation for insulated gate bipolar transistor. The MOSFET is an abbreviation for metal-oxide-semiconductor field-effect transistor. The IPM is an abbreviation for intelligent power module. The drive circuit 81 is connected to the outside of the motor 10 with wiring connected to a connector 82. The wiring connected to the connector 82 passes through through-holes 83 provided in the motor housings 21 and 23.

The circuit board 80 of the first example embodiment is, for example, equipped with the drive circuit 81 and the like for driving the motor assembly 30 described above, and housed in the motor housings 21 and 23.

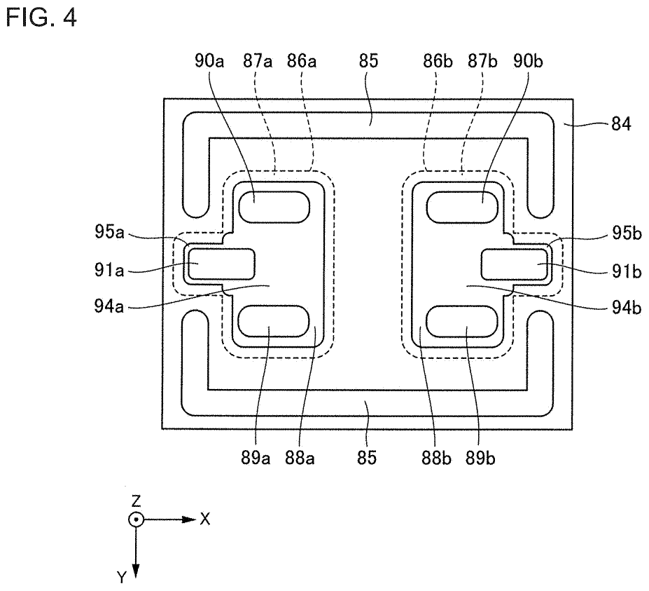

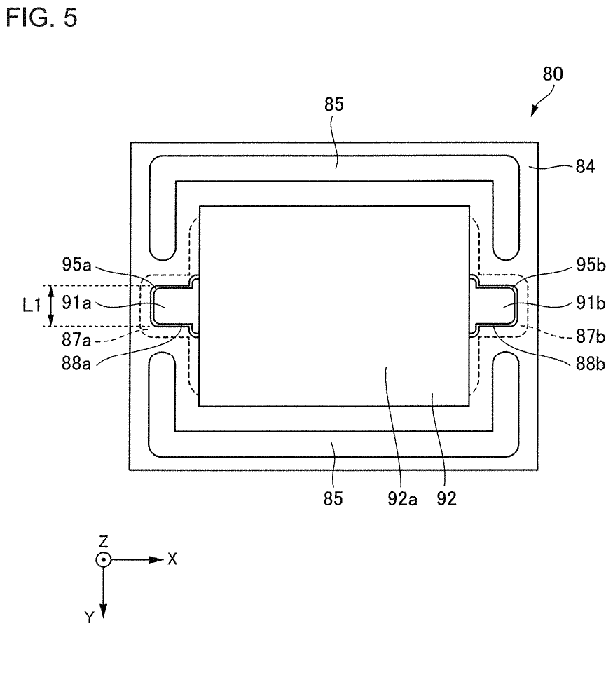

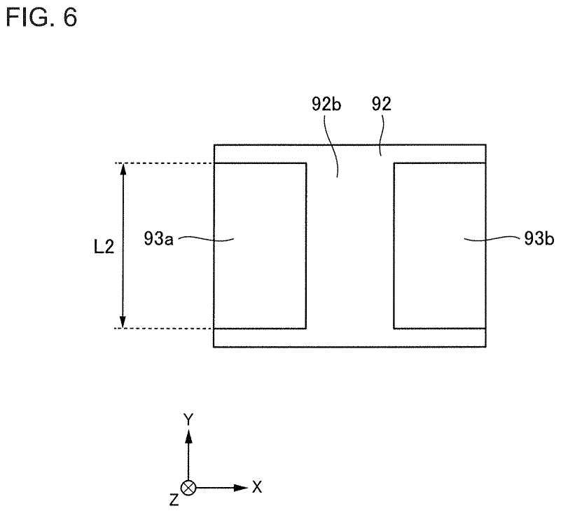

FIG. 4 is a plan view illustrating a board defining a circuit board according to the first example embodiment of the present disclosure. FIG. 4 illustrates a state before electronic components are mounted on the board. FIG. 5 is a plan view illustrating a configuration of the circuit board according to the first example embodiment of the present disclosure. FIG. 5 illustrates a state after the electronic components are mounted on the board. FIG. 6 is a bottom view of the electronic components illustrated in FIG. 5 as viewed from its surface facing the board.

The board 84 is equipped with an electronic component 92. When the electronic component 92 is mounted on the board 84, a reflow method is performed using cream solder. The board 84 is a rigid board. The board 84 may be a flexible board. As a material of the board 84, any known material can be used as long as it is compatible with the reflow method. In the following description, the board 84 is disposed at a position where its mounting surface is orthogonal to the Z axis. The mounting surface of the board 84 is further away on +Z side than a surface of the board 84 opposite to the mounting surface. The electronic component 92 is surface-mounted (also referred to as surface mount) on the mounting surface of the board 84.

The mounting surface of the board 84 includes a circuit pattern made of copper foil. The circuit pattern may be composed of a conductor other than the copper foil. The surface of the board 84 on which the circuit pattern is formed includes a portion covered with a resist and a portion covered with no resist. The portion covered with no resist of the copper foil on the mounting surface of the board 84 is a land. As a method for forming the copper foil and the resist on the board 84, any known method may be used. The mounting surface of the board 84 includes a mark 85 indicating a mounting position of the electronic component 92. The mark 85 is printed on the resist with ink, for example.

The circuit board 80 of the first example embodiment includes the board 84, a land 88a disposed on the board 84, a land 88b disposed on the board 84, the electronic component 92 soldered to the land 88a and the land 88b.

The circuit board 80 includes a copper foil portion 86a disposed on the board 84. The copper foil portion 86a includes a coated copper foil portion 87a covered with a resist, and the land 88a covered with no resist. The circuit board 80 includes a copper foil portion 86b disposed on the board 84. The copper foil portion 86b includes a coated copper foil portion 87b covered with a resist and the land 88b covered with no resist.

The electronic component 92 includes a surface 92b, facing the board 84, and a surface 92a opposite to the surface 92b. The electronic component 92 includes back surface electrode portions 93a and 93b on the surface 92b. The land 88a includes an electrode land portion 94a facing the back surface electrode portion 93a. The land 88b includes an electrode land portion 94b facing the back surface electrode portion 93b.

The land 88a includes a protruding land portion 95a that does not face the electronic component 92 in a state where the electronic component 92 and the board 84 are soldered. The protruding land portion 95a and the electrode land portion 94a are integrated. That is, the protruding land portion 95a and the electrode land portion 94a do not have the portion covered with the resist. The protruding land portion 95a has an area smaller than an area of the electrode land portion 94a. The protruding land portion 95a has a width L1 orthogonal to its protruding direction, the width L1 being narrower than a width L2 of the back surface electrode portion 93a of the electronic component 92, the width L2 being orthogonal to the protruding direction of the protruding land portion 95a.

The land 88b includes a protruding land portion 95b that does not face the electronic component 92 in a state where the electronic component 92 and the board 84 are soldered. The protruding land portion 95b and the electrode land portion 94b are integrated. That is, the protruding land portion 95b and the electrode land portion 94b do not have the portion covered with the resist. The protruding land portion 95b has an area smaller than an area of the electrode land portion 94b.

The coated copper foil portion 87a of the copper foil portion 86a provided on the board 84, being copper foil connected to the periphery of the protruding land portion 95a and covered with a resist, may have an area that is larger than an area of the protruding land portion 95a or that is not larger the area thereof. The coated copper foil portion 87b of the copper foil portion 86b provided on the board 84, being copper foil connected to the periphery of the protruding land portion 95b and covered with a resist, may have an area that is larger than an area of the protruding land portion 95b or that is not larger the area thereof.

The circuit board 80 includes a solder portion 89a and a solder portion 90a that are printed on the electrode land portion 94a. The circuit board 80 also includes a solder portion 91a printed on an upper surface thereof from the protruding land portion 95a to the electrode land portion 94a. The solder portion 89a, the solder portion 90a, and the solder portion 91a are formed by printing, for example, cream solder on the land 88a.

The circuit board 80 includes a solder portion 89b and a solder portion 90b that are printed on the electrode land portion 94b. The circuit board 80 also includes a solder portion 91b printed on an upper surface thereof from the protruding land portion 95b to the electrode land portion 94b. The solder portion 89b, the solder portion 90b, and the solder portion 91b are formed by printing, for example, cream solder on the land 88b.

When the electronic component 92 is mounted on the board 84 in a manufacturing apparatus, the electronic component 92 is placed on the board 84 using the mark 85 on the board 84 as a guide, and heats the circuit board 80 in a reflow furnace. The solder portions 89a, 90a, 91a, 89b, 90b, and 91b are melted by heating, and the electronic component 92 is soldered to the board 84.

In particular, the melted solder portion 91a permeates between the electrode land portion 94a and the back surface electrode portion 93a due to capillarity to solder them. Additionally, the melted solder portion 91b permeates between the electrode land portion 94b and the back surface electrode portion 93b due to capillarity to solder them.

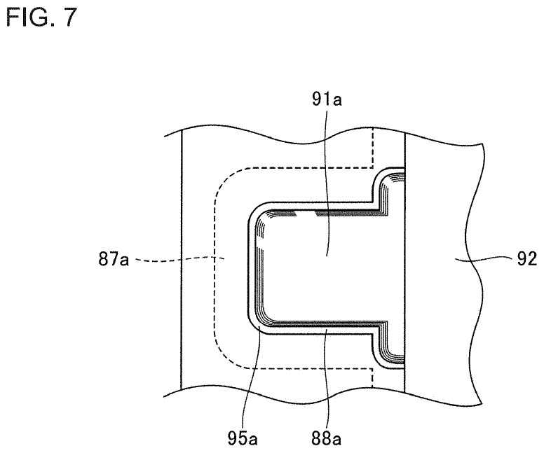

FIG. 7 is a plan view illustrating the vicinity of the protruding land portion 95a in an enlarged manner, in which the electronic component 92 is properly soldered to the board 84.

When the soldering between the electrode land portion 94a and the back surface electrode portion 93a are properly soldered, the solder portion 91a on the protruding land portion 95a penetrates between the electrode land portion 94a and the back surface electrode portion 93a. This causes the solder portion 91a on the protruding land portion 95a to be reduced in height in the Z-axis direction after heating. After the heating, the solder portion 91a causes the protruding land portion 95a to be a wet state. The wet state indicates that the solder portion 91a does not rise in the Z direction due to surface tension on the protruding land portion 95a, and the solder portion 91a spreads in the X-axis direction and the Y-axis direction on the protruding land portion 95a. After the heating, the protruding land portion 95a is soldered in a plating manner using the solder portion 91a.

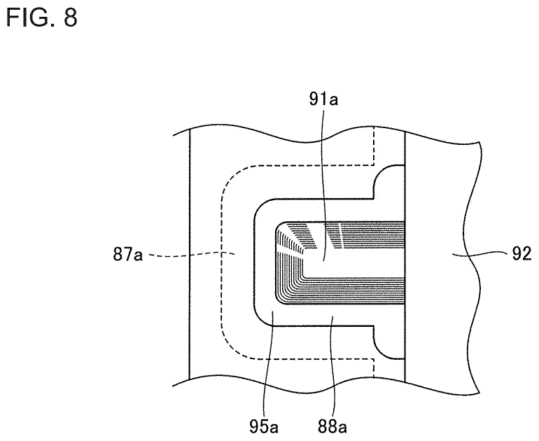

In contrast, FIG. 8 is a plan view illustrating the vicinity of the protruding land portion 95a in an enlarged manner, in which the electronic component 92 is poorly soldered to the board 84.

When the soldering between the electrode land portion 94a and the back surface electrode portion 93a are poorly soldered, the solder portion 91a on the protruding land portion 95a insufficiently penetrates between the electrode land portion 94a and the back surface electrode portion 93a. This causes the solder portion 91a on the protruding land portion 95a to be still high in height in the Z-axis direction even after heating. Even after the heating, the solder portion 91a causes the protruding land portion 95a to be a poorly wet state. The poorly wet state indicates that the solder portion 91a rises in the Z direction due to surface tension on the protruding land portion 95a, or the solder portion 91a does not spread in the X-axis direction and the Y-axis direction on the protruding land portion 95a. In this state, even after the heating, the protruding land portion 95a may not be soldered in a plating manner using the solder portion 91a.

As described with reference to FIGS. 7 and 8, the present example embodiment enables determining whether soldering is properly performed or there is an imperfect solder joint by visually checking a state of the solder portion 91a on the protruding land portion 95a or by checking a captured image thereof, and thus enabling an imperfect solder joint to be easily checked. Although in FIGS. 7 and 8, solder between the electrode land portion 94a and the back surface electrode portion 93a is described, the same applies to solder between the electrode land portion 94b and the back surface electrode portion 93b, and thus the description thereof is eliminated.

A circuit board 180 of a second example embodiment is, for example, equipped with the drive circuit 81 and the like for driving the motor assembly 30 described above, and housed in the motor housings 21 and 23.

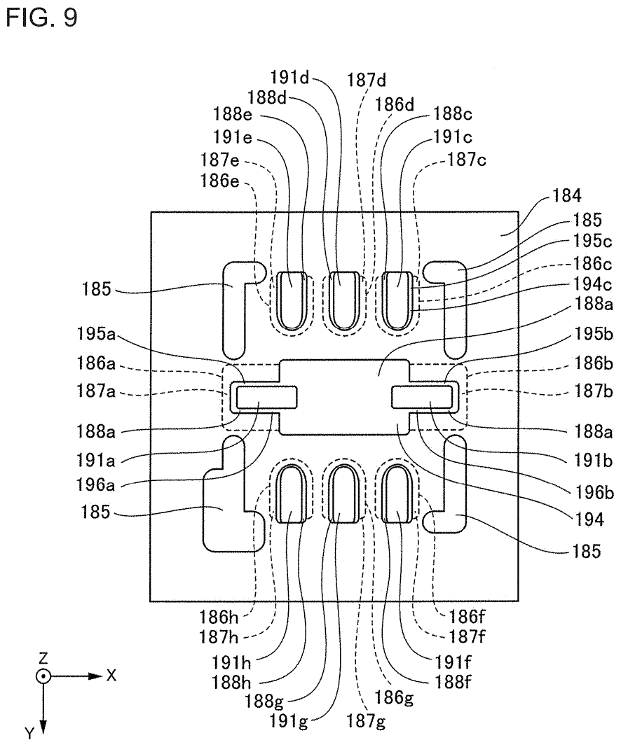

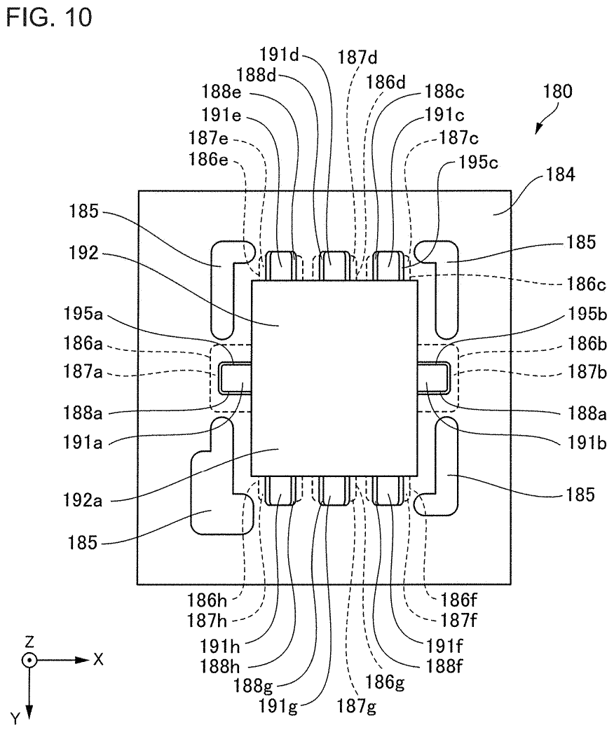

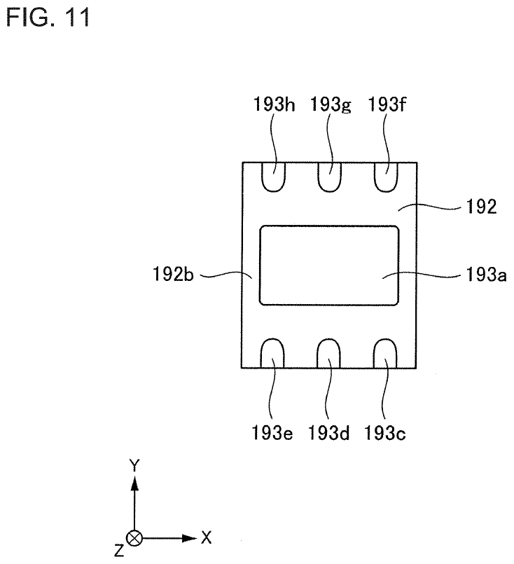

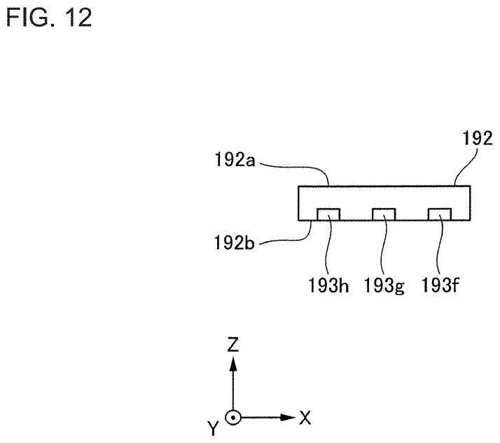

FIG. 9 is a plan view illustrating a board defining a circuit board according to the second example embodiment of the present disclosure. FIG. 9 illustrates a state before electronic components are mounted on the board. FIG. 10 is a plan view illustrating a configuration of the circuit board according to the second example embodiment of the present disclosure. FIG. 10 illustrates a state after the electronic components are mounted on the board. FIG. 11 is a bottom view of the electronic components illustrated in FIG. 10 as viewed from its surface facing the board. FIG. 12 is a side view of the electronic component illustrated in FIG. 10 as viewed from a plane orthogonal to the board.

A board 184 is equipped with an electronic component 192. When the electronic component 192 is mounted on the board 184, a reflow method is performed using cream solder. The board 184 is a rigid board. The board 184 may be a flexible board. As a material of the board 184, any known material can be used as long as it is compatible with the reflow method. In the following description, the board 184 is disposed at a position where its mounting surface is orthogonal to the Z axis. The mounting surface of the board 184 is further away on +Z side than a surface of the board 184 opposite to the mounting surface. The electronic component 192 is surface-mounted (also referred to as surface mount) on the mounting surface of the board 184.

The mounting surface of the board 184 includes a circuit pattern made of copper foil. The circuit pattern may be composed of a conductor other than the copper foil. The surface of the board 184 on which the circuit pattern is formed includes a portion covered with a resist and a portion covered with no resist. The portion covered with no resist of the copper foil on the mounting surface of the board 184 is a land. As a method for forming the copper foil and the resist on the board 184, any known method may be used. The mounting surface of the board 184 includes a mark 185 indicating a mounting position of the electronic component 192. The mark 185 is printed on the resist with ink, for example.

The circuit board 180 of the second example embodiment includes the board 184, lands 188a, 188c, 188d, 188e, 188f, 188g, and 188h disposed on the board 184, and the electronic component 192 soldered to the lands 188a, 188c, 188d, 188e, 188f, 188g, and 188h.

The circuit board 180 includes a copper foil portion 186a disposed on the board 184. The copper foil portion 186a includes a coated copper foil portion 187a covered with a resist, and the land 188a covered with no resist.

The circuit board 180 includes a copper foil portion 186b disposed on the board 184. The copper foil portion 186b includes a coated copper foil portion 187b covered with a resist and the land 188a covered with no resist.

The circuit board 180 includes a copper foil portion 186c disposed on the board 184. The copper foil portion 186c includes a coated copper foil portion 187c covered with a resist and the land 188c covered with no resist.

The circuit board 180 includes a copper foil portion 186d disposed on the board 184. The copper foil portion 186d includes a coated copper foil portion 187d covered with a resist and the land 188d covered with no resist.

The circuit board 180 includes a copper foil portion 186e disposed on the board 184. The copper foil portion 186e includes a coated copper foil portion 187e covered with a resist and the land 188e covered with no resist.

The circuit board 180 includes a copper foil portion 186f disposed on the board 184. The copper foil portion 186f includes a coated copper foil portion 187f covered with a resist and the land 188f covered with no resist.

The circuit board 180 includes a copper foil portion 186g disposed on the board 184. The copper foil portion 186g includes a coated copper foil portion 187g covered with a resist and the land 188g covered with no resist.

The circuit board 180 includes a copper foil portion 186h disposed on the board 184. The copper foil portion 186h includes a coated copper foil portion 187h covered with a resist and the land 188h covered with no resist.

The electronic component 192 includes a surface 192b, facing the board 184, and a surface 192a opposite to the surface 192b. The electronic component 192 includes a back surface electrode portion 193a on the surface 192b. The land 188a includes an electrode land portion 194 facing the back surface electrode portion 193a.

The electronic component 192 includes back surface electrode portions 193c, 193d, 193e, 193f, 193g and 193h on the surface 192b. Each of the back surface electrode portions 193c, 193d, 193e, 193f, 193g and 193h extends to an end portion of the electronic component 192 in a direction parallel to a mounting surface of the board 184, and further extends to a side surface of the electronic component 192, the side surface being orthogonal to the mounting surface of the board 184.

The land 188c includes an electrode land portion 194c facing the back surface electrode portion 193c. The lands 188d, 188e, 188f, 188g, and 188h are each similar to the land 188c, so that description of the lands 188d, 188e, 188f, 188g and 188h is eliminated.

The land 188a includes a protruding land portion 195a that does not face the electronic component 192 in a state where the electronic component 192 and the board 184 are soldered. The protruding land portion 195a and the electrode land portion 194 are integrated. The land 188a includes a protruding land portion 195b that does not face the electronic component 192 in a state where the electronic component 192 and the board 184 are soldered. The protruding land portion 195b and the electrode land portion 194 are integrated.

The land 188a includes a connecting land portion 196a that is provided between the electrode land portion 194 and the protruding land portion 195a and that connects the electrode land portion 194 and the protruding land portion 195a. The land (land 188a) provided with the connecting land portion 196a is integrated with the land (land 188a) provided with the electrode land portion 194.

The land 188a includes a connecting land portion 196b that is provided between the electrode land portion 194 and the protruding land portion 195b and that connects the electrode land portion 194 and the protruding land portion 195b. The land (land 188a) provided with the connecting land portion 196b is integrated with the land (land 188a) provided with the electrode land portion 194.

The land 188c includes a protruding land portion 195c that does not face the electronic component 192 in a state where the electronic component 192 and the board 184 are soldered. The protruding land portion 195c and the electrode land portion 194c are integrated. The lands 188d, 188e, 188f, 188g, and 188h are each similar to the land 188c, so that description of the lands 188d, 188e, 188f, 188g and 188h is eliminated.

The circuit board 180 includes a solder portion 191a printed on an upper surface thereof from the protruding land portion 195a to the electrode land portion 194. The circuit board 180 includes a solder portion 191b printed on an upper surface thereof from the protruding land portion 195b to the electrode land portion 194.

The solder portions 191a and 191b are formed by printing, for example, cream solder on the land 188a.

The circuit board 180 includes a solder portion 191c printed on an upper surface thereof from the protruding land portion 195c to the electrode land portion 194c. The circuit board 180 also includes solder portions 191d, 191e, 191f, 191g, and 191h on the lands 188d, 188e, 188f, 188g, and 188h, respectively.

The solder portions 191c, 191d, 191e, 191f, 191g, and 191h are formed by printing, for example, cream solder on the lands 188c, 188d, 188e, 188f, 188g, and 188h, respectively.

When the electronic component 192 is mounted on the board 184 in a manufacturing apparatus, the electronic component 192 is placed on the board 184 using the mark 185 on the board 184 as a guide, and the circuit board 180 is heated in a reflow furnace. The solder portions 191a, 191b, 191c, 191d, 191e, 191f, 191g, and 191h are melted by heating, and the electronic component 192 is soldered to the board 184.

The melted solder portion 191a permeates between the electrode land portion 194 and the back surface electrode portion 193a due to capillarity to solder them. Additionally, the melted solder portion 191b permeates between the electrode land portion 194 and the back surface electrode portion 193a due to capillarity to solder them.

When a solder state of the protruding land portions 195a and 195b is checked by visually checking or checking an image thereof, an imperfect solder joint between the electrode land portion 194 and the back surface electrode portion 193a can be checked.

The melted solder portion 191c permeates between the electrode land portion 194c and the back surface electrode portion 193c due to capillarity to solder them. The melted solder portion 191c also solders and connects the protruding land portion 195c and a portion of the back surface electrode portion 193c, the portion being on the side surface of the electronic component 192. When a solder state of the protruding land portions 195c is checked by visually checking or checking an image thereof, an imperfect solder joint between the electrode land portion 194c and the back surface electrode portion 193c can be checked.

The solder portions 191d, 191e, 191f, 191g and 191h are each similar to the solder portions 191c, so that description of the solder portions 191d, 191e, 191f, 191g and 191h is eliminated.

A circuit board 280 of a third example embodiment is, for example, equipped with the drive circuit 81 and the like for driving the motor assembly 30 described above, and housed in the motor housings 21 and 23.

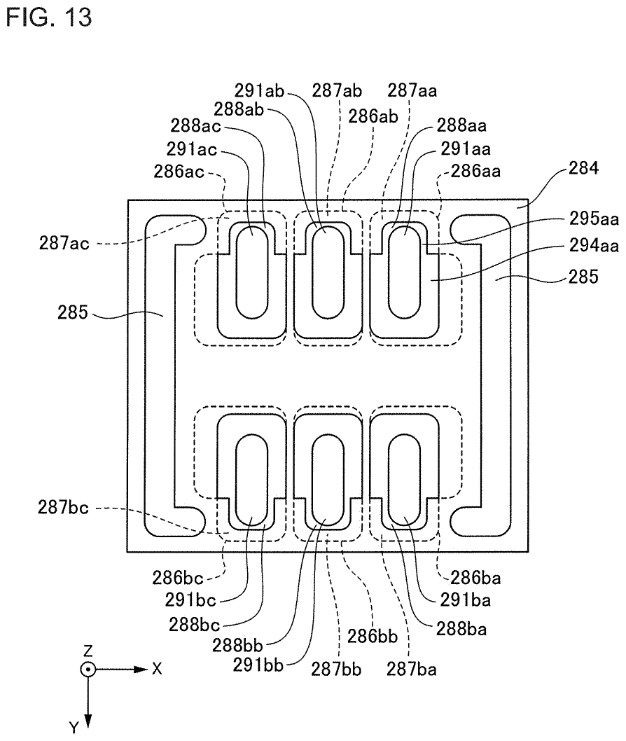

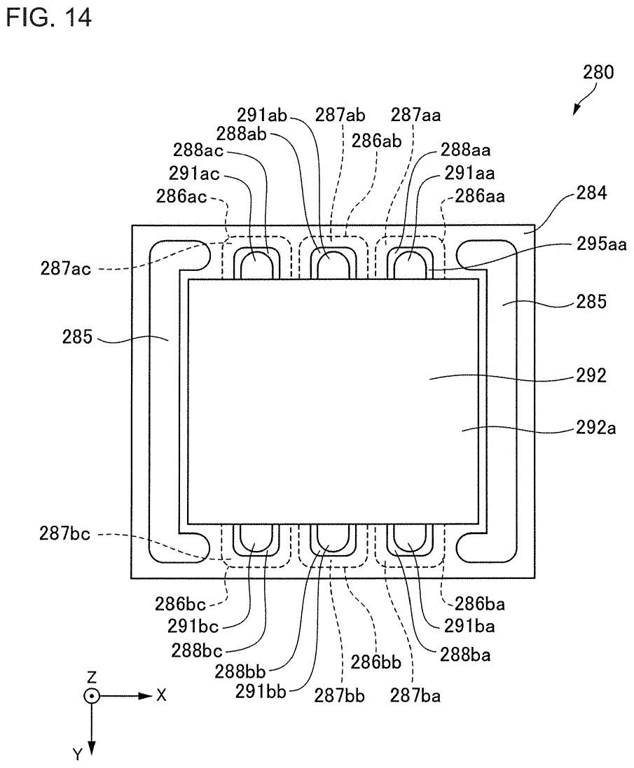

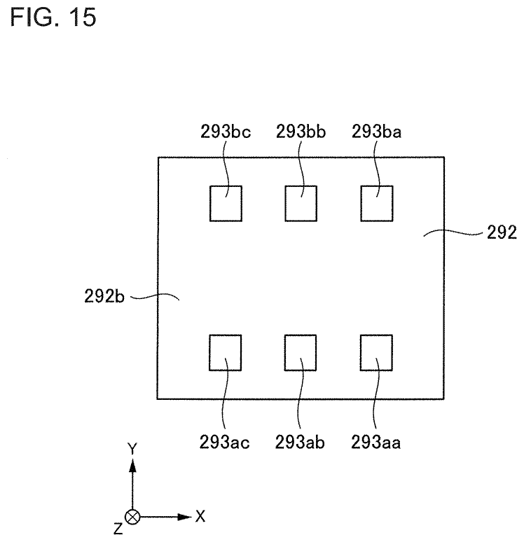

FIG. 13 is a plan view illustrating a board defining a circuit board according to the third example embodiment of the present disclosure. FIG. 13 illustrates a state before electronic components are mounted on the board. FIG. 14 is a plan view illustrating a configuration of the circuit board according to the third example embodiment of the present disclosure. FIG. 14 illustrates a state after the electronic components are mounted on the board. FIG. 15 is a bottom view of the electronic components illustrated in FIG. 14 as viewed from its surface facing the board.

A board 284 is equipped with an electronic component 292. When the electronic component 292 is mounted on the board 284, a reflow method is performed using cream solder. The board 284 is a rigid board. The board 284 may be a flexible board. As a material of the board 284, any known material can be used as long as it is compatible with the reflow method. In the following description, the board 284 is disposed at a position where its mounting surface is orthogonal to the Z axis. The mounting surface of the board 284 is further away on +Z side than a surface of the board 284 opposite to the mounting surface. The electronic component 292 is surface-mounted (also referred to as surface mount) on the mounting surface of the board 284.

The mounting surface of the board 284 includes a circuit pattern made of copper foil. The circuit pattern may be composed of a conductor other than the copper foil. The surface of the board 284 on which the circuit pattern is formed includes a portion covered with a resist and a portion covered with no resist. The portion covered with no resist of the copper foil on the mounting surface of the board 284 is a land. As a method for forming the copper foil and the resist on the board 284, any known method may be used. The mounting surface of the board 284 includes a mark 285 indicating a mounting position of the electronic component 292. The mark 285 is printed on the resist with ink, for example.

The circuit board 280 of the third example embodiment includes the board 284, lands 288aa, 288ab, 288ac, 288ba, 288bb, and 288bc, being disposed on the board 284, and the electronic component 292 soldered to the lands 288aa, 288ab, 288ac, 288ba, 288bb, and 288bc.

The circuit board 280 includes a copper foil portion 286aa disposed on the board 284. The copper foil portion 286aa includes a coated copper foil portion 287aa covered with a resist, and the land 288aa covered with no resist.

The circuit board 280 includes a copper foil portion 286ab disposed on the board 284. The copper foil portion 286ab includes a coated copper foil portion 287ab covered with a resist, and the land 288ab covered with no resist.

The circuit board 280 includes a copper foil portion 286ac disposed on the board 284. The copper foil portion 286ac includes a coated copper foil portion 287ac covered with a resist, and the land 288ac covered with no resist.

The circuit board 280 includes a copper foil portion 286ba disposed on the board 284. The copper foil portion 286ba includes a coated copper foil portion 287ba covered with a resist, and the land 288ba covered with no resist.

The circuit board 280 includes a copper foil portion 286bb disposed on the board 284. The copper foil portion 286bb includes a coated copper foil portion 287bb covered with a resist and the land 288bb covered with no resist.

The circuit board 280 includes a copper foil portion 286bc disposed on the board 284. The copper foil portion 286bc includes a coated copper foil portion 287bc covered with a resist and the land 288bc covered with no resist.

The electronic component 292 includes a surface 292b, facing the board 284, and a surface 292a opposite to the surface 292b.

The electronic component 292 includes back surface electrode portions 293aa, 293ab, 293ac, 293ba, 293bb, and 293bc on the surface 292b.

The land 288aa includes an electrode land portion 294aa facing the back surface electrode portion 293aa. The lands 288ab, 288ac, 288ba, 288bb, and 288bc are each similar to the lands 288aa, so that description of the lands 288ab, 288ac, 288ba, 288bb, and 288bc is eliminated.

The land 288aa includes a protruding land portion 295aa that does not face the electronic component 292 in a state where the electronic component 292 and the board 284 are soldered. The protruding land portion 295aa and the electrode land portion 294aa are integrated. The lands 288ab, 288ac, 288ba, 288bb, and 288bc are each similar to the lands 288aa, so that description of the lands 288ab, 288ac, 288ba, 288bb, and 288bc is eliminated.

The circuit board 280 also includes a solder portion 291aa printed on an upper surface thereof from the protruding land portion 295aa to the electrode land portion 294aa. The circuit board 280 also includes solder portions 291ab, 291ac, 291ba, 291bb, and 291bc on the lands 288ab, 288ac, 288ba, 288bb, and 288bc, respectively.

The solder portions 291aa, 291ab, 291ac, 291ba, 291bb, and 291bc are formed by printing, for example, cream solder on the lands 288aa, 288ab, 288ac, 288ba, 288bb, and 288bc, respectively.

When the electronic component 292 is mounted on the board 284 in a manufacturing apparatus, the electronic component 292 is placed on the board 284 using the mark 285 on the board 284 as a guide, and the circuit board 280 is heated in a reflow furnace. The solder portions 291aa, 291ab, 291ac, 291ba, 291bb, and 291bc are melted by heating, and the electronic component 292 is soldered to the board 284.

The melted solder portion 291aa permeates between the electrode land portion 294aa and the back surface electrode portion 293aa due to capillarity to solder them. When a solder state of the protruding land portions 295aa is checked by visually checking or checking an image thereof, an imperfect solder joint between the electrode land portion 294aa and the back surface electrode portion 293aa can be checked.

The solder portions 291ab, 291ac, 291ba, 291bb, and 291bc are each similar to the solder portions 291aa, so that description of the solder portions 291ab, 291ac, 291ba, 291bb, and 291bc is eliminated.

Next, action and effect of the circuit boards 80, 180, and 280 will be described.

In the disclosure according to the above-described example embodiment, a circuit board includes a board, a land disposed on the board, and an electronic component soldered to the land, the electronic component being provided on its surface with a back surface electrode portion, the surface facing the board, the land including an electrode land portion and a protruding land portion, the back surface electrode portion facing the electrode land portion in a state where the electronic component and the board are soldered, and the protruding land portion and the electrode land portion being integrated.

This enables an imperfect solder joint to be easily checked.

When a solder state of the protruding land portion is visually checked or an image thereof is checked, an imperfect solder joint of the electronic component can be checked.

The protruding land portion is soldered in a plating manner.

Thus, when the protruding land portion is visually checked or an image thereof is checked whether it is soldered in a plating manner, the electronic component can be checked whether it has an imperfect solder joint.

The land includes a connecting land portion that is provided between the electrode land portion and the protruding land portion and that connects the electrode land portion and the protruding land portion, and the land provided with the connecting land portion is integrated with the land provided with the electrode land portion.

Thus, even when the back surface electrode portion of the electronic component is disposed closer to the center of the electronic component than an end portion thereof, the connecting land portion enables solder to be reliably drawn into the electrode land portion.

The land is copper foil covered with no resist of copper foil provided on the board, and the copper foil provided on the board includes copper foil that is connected to the periphery of the land and covered with a resist.

This enables heat of the copper foil covered with the resist to be transferred to the land, so that the heat of the land can sufficiently melt solder to allow the solder to be more reliably drawn into the electrode land portion.

The copper foil provided on the board includes copper foil that is connected to the periphery of the protruding land portion and covered with a resist and that has an area larger than an area of the protruding land portion.

This enables heat of the copper foil covered with the resist to be transferred to a protruding land, so that the heat of the land can sufficiently melt solder to allow the solder to be more reliably drawn into the electrode land portion.

The protruding land portion has an area smaller than an area of the electrode land portion.

This enables reducing the amount of the cream solder in the protruding land portion, the cream solder remaining without being drawn into the electrode land portion, and the solder in the protruding land portion to be more in a plating manner.

The protruding land portion has a width that is orthogonal to its protruding direction and is narrower than a width of the back surface electrode portion orthogonal to the protruding direction.

Thus, when the protruding land portion is drawn out thinner than the electrode land portion, displacement of the electronic component in the protruding direction can be prevented.

A circuit board includes a board, a first land disposed on the board, and an electronic component soldered to the first land, the electronic component being provided on its surface with a first back surface electrode portion, the surface facing the circuit board, the first back surface electrode portion facing a first electrode land portion provided on the first land, the first back surface electrode portion extending to an end portion of the electronic component in a direction parallel to a mounting surface of the board and further extending to a side surface of the electronic component, the side surface being orthogonal to the mounting surface of the board, the first land including a protruding land portion connected to the first electrode land portion at a position that does not face the electronic component, and the first land provided with the protruding land portion being integrated with the first land provided with the first electrode land portion.

Thus, an imperfect solder joint of the first back surface electrode portion can be determined by checking a state of solder of a first protruding land portion.

The protruding land portion is a first protruding land portion, and a second land disposed on the board is provided. The electronic component is soldered to the second land, and the electronic component is provided on its surface, facing the board, with a second back surface electrode portion. The second back surface electrode portion faces a second electrode land portion provided on the second land. The second land includes a second protruding land portion without facing the electronic component. The second land provided with the second protruding land portion is integrated with the second land provided with the second electrode land portion.

Thus, an imperfect solder joint of the second back surface electrode portion can be determined by checking a state of solder of the second protruding land portion.

The second protruding land portion is soldered in a plating manner.

Thus, when the second protruding land portion is visually checked or an image thereof is checked whether it is soldered in a plating manner, the electronic component can be checked whether it has an imperfect solder joint.

The board is equipped with a motor drive circuit for driving a motor.

Thus, when an image of a state of solder in the motor drive circuit is checked, an imperfect solder joint therein can be checked.

A motor includes the circuit board equipped with the motor drive circuit and a motor assembly driven by the motor drive circuit.

Thus, when an image of a state of solder in the motor is checked, an imperfect solder joint therein can be checked.

The motor is configured to rotate a fan.

Thus, when an image of a state of solder in the motor for a fan is checked, an imperfect solder joint therein can be checked.

The application of the motor provided with the circuit board of the above-described example embodiment is not particularly limited. The motor of the above-described example embodiment is, for example, a motor that rotates an axial fan. Each of the above-described configurations can be appropriately combined within a range consistent with each other.

Although the example embodiments of the present disclosure have been described above, the present disclosure is not limited to these example embodiments, and various modifications and changes can be made within the scope of the gist thereof. These example embodiments and modifications thereof are included in not only the scope and gist of the disclosure, but also the disclosure described in the scope of claims and the equivalent scope thereof.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A circuit board comprising:
a board;
a land on the board; and
an electronic component soldered to the land; wherein
the electronic component includes a surface with a back surface electrode portion, the surface opposing the board;
the land includes an electrode land portion and a protruding land portion;
the back surface electrode portion opposes the electrode land portion in a state where the electronic component and the board are soldered; and
the protruding land portion and the electrode land portion are integrated.

2. The circuit board according to claim 1, wherein the protruding land portion is soldered to define a plated structure.

3. The circuit board according to claim 1, wherein
the land includes a connecting land portion that is provided between the electrode land portion and the protruding land portion and that connects the electrode land portion and the protruding land portion; and
the land provided with the connecting land portion is integrated with the land provided with the electrode land portion.

4. The circuit board according to claim 1, wherein
the land includes a copper foil without any resist and a copper foil provided on the board; and
the copper foil provided on the board is connected to a periphery of the land and covered with a resist.

5. The circuit board according to claim 4, wherein the copper foil provided on the board includes copper foil that is connected to a periphery of the protruding land portion and covered with a resist and has an area larger than an area of the protruding land portion.

6. The circuit board according to claim 1, wherein the protruding land portion has an area smaller than an area of the electrode land portion.

7. The circuit board according to claim 1, wherein the protruding land portion has a width that is orthogonal to a protruding direction and is narrower than a width of the back surface electrode portion orthogonal to the protruding direction.

8. A circuit board comprising:
a board;
a first land on the board; and
an electronic component soldered to the first land; wherein
the electronic component includes a surface with a first back surface electrode portion, the surface opposing the circuit board;
the first back surface electrode portion opposes a first electrode land portion provided on the first land;
the first back surface electrode portion extends to an end portion of the electronic component in a direction parallel to a mounting surface of the board and extends to a side surface of the electronic component, the side surface being orthogonal to the mounting surface of the board;
the first land includes a protruding land portion connected to the first electrode land portion at a position that does not oppose the electronic component; and
the first land provided with the protruding land portion is integrated with the first land provided with the first electrode land portion.

9. The circuit board according to claim 8, wherein
the protruding land portion is a first protruding land portion;
a second land is provided on the board;
the electronic component is soldered to the second land;
the electronic component includes a surface, opposing the board, with a second back surface electrode portion;
the second back surface electrode portion opposes a second electrode land portion provided on the second land;
the second land includes a second protruding land portion without opposing the electronic component; and
the second land provided with the second protruding land portion is integrated with the second land provided with the second electrode land portion.

10. The circuit board according to claim 9, wherein
the second protruding land portion is soldered to define a plated structure.

11. The circuit board according to claim 1, wherein
the board includes a motor drive circuit to drive a motor.

12. A motor comprising:
the circuit board including the motor drive circuit according to claim 11; and
a motor assembly driven by the motor drive circuit.

13. The motor according to claim 12, wherein
the motor is configured to rotate a fan.
